(19) United States
(12) Patent Application Publication
(10) Pub. No.: US 2024/0321986 A1
(43) Pub. Date: Sep. 26, 2024

(54) SEMICONDUCTOR DEVICE AND POWER CONVERTER

(71) Applicant: Mitsubishi Electric Corporation, Chiyoda-ku, Tokyo (JP)

(72) Inventor: Kazunari NAKATA, Tokyo (JP)

(73) Assignee: Mitsubishi Electric Corporation, Chiyoda-ku, Tokyo (JP)

(21) Appl. No.: 18/577,041

(22) PCT Filed: Sep. 20, 2022
(86) PCT No.: PCT/JP2022/034929

§ 371 Date: Jan. 5, 2024

(30) Foreign Application Priority Data
Sep. 22, 2021 (JP) 2021-154055

(51) Int. Cl. H01L 29/423; H01L 27/07; H01L 27/088; H01L 29/06; H01L 29/66

(52) U.S. Cl. CPC H01L 29/4236; H01L 27/0727; H01L 27/088; H01L 29/0696; H01L 29/66325

(57) ABSTRACT

It is an object of the present disclosure to provide a semiconductor device having improved reliability of an outer peripheral portion. In plan view, a first angle between a first side surface and a direction of extension of a trench gate is smaller than a second angle between a second side surface and the direction of extension of the trench gate, or the first side surface is parallel to the direction of extension of the trench gate. A thickness of a first amorphous layer in a direction from the first side surface toward an inside of a semiconductor substrate is different from a thickness of a second amorphous layer in a direction from the second side surface toward the inside of the semiconductor substrate.

### TECHNICAL FIELD

The present disclosure relates to semiconductor devices and power converters.

### BACKGROUND ART

With application of semiconductor devices to power control technology, development of smaller and more efficient semiconductor devices has progressed. In steps of manufacturing a semiconductor device, it is usual to cut, after a plurality of semiconductor devices are formed on a single semiconductor wafer, individual semiconductor devices from the wafer (see Patent Documents 1 and 2, for example).

### PRIOR ART DOCUMENTS

### Patent Documents

Patent Document 1: WO 2020/255944
Patent Document 2: Japanese Patent Application Laid-Open No. 2020-36048

### SUMMARY

### Problem to be Solved by the Invention

When a semiconductor device is cut from the semiconductor wafer, cracking, chipping, and the like occur in an outer peripheral portion of the semiconductor device due to an external force applied to the semiconductor wafer by cleavage, for example. In a case where a temperature of the semiconductor device varies due to switching operation and the like, physical breakage and characteristic deterioration of the semiconductor device might originate from a crack or a chip in the outer periphery portion. This leads to reduction in reliability of the semiconductor device.

It is an object of the present disclosure to provide a semiconductor device having improved reliability of an outer peripheral portion to solve the above-mentioned problem.

### Means to Solve the Problem

A semiconductor device according to the present disclosure includes: a semiconductor substrate, a trench gate, a first amorphous layer, and a second amorphous layer. The semiconductor substrate includes a semiconductor element being at least one of a transistor and a diode. The trench gate includes an electrode to control a state of the semiconductor element. The trench gate is provided in an upper surface of the semiconductor substrate. The first amorphous layer is disposed in a first side surface of the semiconductor substrate. The second amorphous layer is disposed in a second side surface of the semiconductor substrate. In plan view, a first angle between the first side surface and a direction of extension of the trench gate is smaller than a second angle between the second side surface and the direction of extension of the trench gate, or the first side surface is parallel to the direction of extension of the trench gate. A thickness of the first amorphous layer in a direction from the first side surface toward an inside of the semiconductor substrate is different from a thickness of the second amorphous layer in a direction from the second side surface toward the inside of the semiconductor substrate.

### Effects of the Invention

According to the present disclosure, reliability of an outer peripheral portion of the semiconductor device is improved.

The objects, features, aspects, and advantages of the present disclosure will become more apparent from the following detailed description when taken in conjunction with the accompanying drawings.

### BRIEF DESCRIPTION OF DRAWINGS

FIG. 1 is a perspective view illustrating a configuration of a semiconductor device according to Embodiment 1.

FIG. 2 is a cross-sectional view taken along the line A-A′ of FIG. 1.

FIG. 3 is a diagram illustrating a detailed configuration on an upper surface of the semiconductor device.

FIG. 4 is a cross-sectional view illustrating a configuration of a transistor region in Embodiment 1.

FIG. 5 is a cross-sectional view illustrating a configuration of an end portion of the semiconductor device.

FIG. 6 is an enlarged cross-sectional view illustrating the configuration of the end portion of the semiconductor device.

FIG. 7 is a diagram showing one example of a transmission electron microscopy image of a first amorphous layer in Embodiment 1.

FIG. 8 is a flowchart showing steps of manufacturing the semiconductor device according to Embodiment 1.

FIG. 9 is a plan view illustrating a configuration of an n type SiC wafer.

FIG. 10 is a plan view illustrating the n type SiC wafer on which semiconductor devices have been formed.

FIG. 11 is a diagram illustrating a step of forming an n type drift layer.

FIG. 12 is a diagram illustrating a step of forming a p type base layer.

FIG. 13 is a diagram illustrating a step of forming n type source layers.

FIG. 14 is a diagram illustrating a step of forming trenches.

FIG. 15 is a diagram illustrating a step of forming p type bottom base layers.

FIG. 16 is a diagram illustrating a step of forming gate dielectric films.

FIG. 17 is a diagram illustrating a step of forming gate electrodes.

FIG. 18 is a diagram illustrating a step of removing an excess portion of the gate electrodes.

FIG. 19 is a diagram illustrating a step of forming oxidation layers.

FIG. 20 is a diagram illustrating a step of forming an interlayer dielectric film.

FIG. 21 is a diagram illustrating a step of forming a source electrode.

FIG. 22 is a diagram illustrating a step of thinning an n type SiC layer.

FIG. 23 is a diagram illustrating a step of forming a drain electrode.

FIG. 24 is a diagram illustrating a step of forming first amorphous layers.

FIG. 25 is a diagram showing a relationship between a distance between an amorphous layer and the interlayer dielectric film and a source-drain leakage current.

FIG. 26 is a diagram illustrating the semiconductor device mounted to leads.

FIG. 27 is a diagram showing a relationship between a thickness of a first amorphous layer and chip failure probability.

FIG. 28 is a bird's eye view schematically showing a configuration of an inside of the semiconductor device according to Embodiment 1.

FIG. 29 is a diagram illustrating a configuration of the semiconductor device in a plane orthogonal to a direction of extension of trench gates.

FIG. 30 is a diagram illustrating a configuration of the semiconductor device in a plane parallel to the direction of extension of the trench gates.

FIG. 31 is a perspective view illustrating a configuration of a semiconductor device according to Embodiment 2.

FIG. 32 is a cross-sectional view taken along the line B-B′ of FIG. 31.

FIG. 33 is a diagram showing a correspondence between a second side surface of the semiconductor device shown schematically and an optical microscope image of the second side surface.

FIG. 34 is a schematic diagram showing the semiconductor device according to Embodiment 2 undergoing a three-point bending test.

FIG. 35 is a diagram showing a relationship between a width of a single-crystal layer in a second side surface and a transverse strength of the semiconductor device.

FIG. 36 is a perspective view illustrating a configuration of a semiconductor device according to Embodiment 3.

FIG. 37 is a cross-sectional view taken along the line C-C′ of FIG. 36.

FIG. 38 is a diagram illustrating a step of forming upper surface side first amorphous layers.

FIG. 39 is a diagram illustrating a configuration of the semiconductor device in the plane orthogonal to the direction of extension of the trench gates.

FIG. 40 is a diagram showing a relationship between a difference in thickness between an upper first amorphous layer and a lower first amorphous layer and the transverse strength of the semiconductor device.

FIG. 41 is a diagram illustrating a configuration of the semiconductor device in the plane parallel to the direction of extension of the trench gates.

FIG. 42 is a block diagram showing configurations of a power converter and a power conversion system according to Embodiment 4.

### DESCRIPTION OF EMBODIMENTS

### Embodiment 1

In description made below, an n type and a p type indicate conductivity types of semiconductors. The p type and the n type may be interchanged with each other.

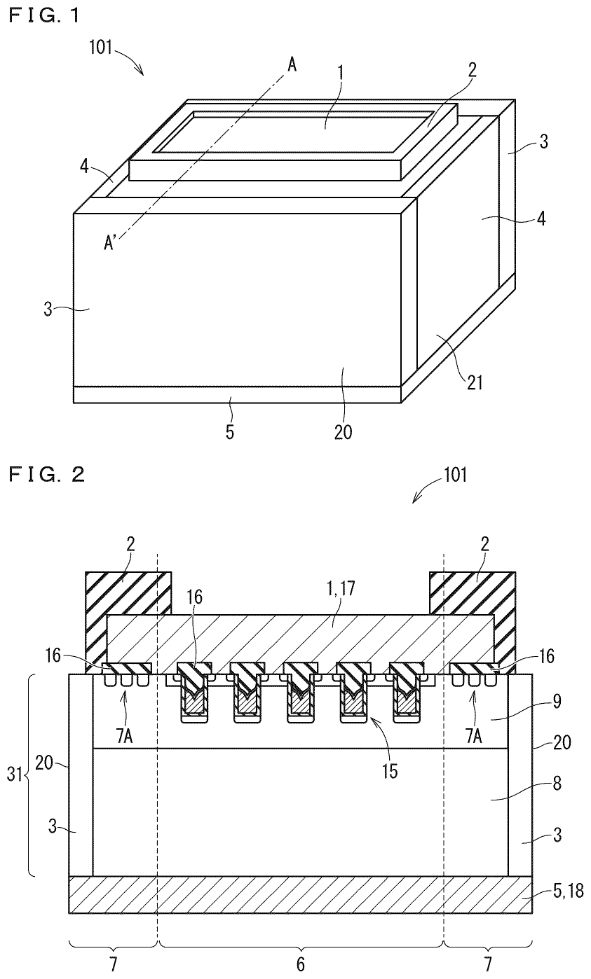

FIG. 1 is a perspective view illustrating a configuration of a semiconductor device 101 according to Embodiment 1. FIG. 2 is a cross-sectional view taken along the line A-A′ of FIG. 1.

The semiconductor device 101 includes a semiconductor substrate 31, a transistor region 6, trench gates 15, a termination region 7, a front surface electrode 1, an outer peripheral insulating layer 2, a back surface electrode 5, first amorphous layers 3, and second amorphous layers 4.

The semiconductor substrate 31 is formed of a semiconductor such as Si or a so-called wide bandgap semiconductor such as SiC, GaN, and gallium oxide, for example. The semiconductor substrate 31 is rectangular in plan view. The semiconductor substrate 31 has two opposing first side surfaces 20 and two opposing second side surfaces 21. The first side surfaces 20 are not parallel to the second side surfaces 21.

The transistor region 6 corresponds to a region of the semiconductor substrate 31 in which a transistor is formed. In other words, the semiconductor substrate 31 includes the transistor.

The trench gates 15 are provided in an upper surface of the semiconductor substrate 31. The trench gates 15 form a portion of the transistor. For example, one transistor cell corresponds to each of regions obtained by partitioning per trench gate 15. The trench gates 15 extend in one direction in the upper surface of the semiconductor substrate 31. The trench gates 15 herein extend in a depth direction in FIG. 2, in other words, in a left-right direction in FIG. 1. In Embodiment 1, the first side surfaces 20 of the semiconductor substrate 31 are parallel to a direction of extension of the trench gates 15. The second side surfaces 21 of the semiconductor substrate 31 are orthogonal to the direction of extension of the trench gates 15.

The termination region 7 is provided to surround the transistor region 6. A breakdown voltage holding structure 7A is disposed in the termination region 7. The breakdown voltage holding structure 7A holds a breakdown voltage of the transistor. Various structures are selected for the breakdown voltage holding structure 7A as appropriate. The breakdown voltage holding structure 7A is a field limiting ring (FLR), variation of lateral doping (VLD), and the like formed in a surface layer on a side of the upper surface of the semiconductor substrate 31, for example.

The first amorphous layers 3 are formed in the first side surfaces 20 of the semiconductor substrate 31. The second amorphous layers 4 are formed in the second side surfaces 21 of the semiconductor substrate 31. A thickness of each of the first amorphous layers 3 is different from a thickness of each of the second amorphous layers 4. The thickness of each of the first amorphous layers 3 corresponds to a dimension in a direction from a first side surface 20 toward an inside of the semiconductor substrate 31. Similarly, the thickness of each of the second amorphous layers 4 corresponds to a dimension in a direction from a second side surface 21 toward the inside of the semiconductor substrate 31. The first amorphous layers 3 may be formed in portions of the first side surfaces 20 or may be formed in the entire first side surfaces 20. Similarly, the second amorphous layers 4 may be formed in portions of the second side surfaces 21 or may be formed in the entire second side surfaces 21.

The first amorphous layers 3 and the second amorphous layers 4 include the same element as an element forming a crystal of the semiconductor substrate 31. In Embodiment 1, the semiconductor substrate 31 is formed of single-crystal SiC except for portions of the first amorphous layers 3 and the second amorphous layers 4. The first amorphous layers 3 and the second amorphous layers 4 are formed of amorphous SiC.

The front surface electrode 1 is disposed over the upper surface of the semiconductor substrate 31. The front surface electrode 1 is electrically connected to the transistor. The front surface electrode 1 herein corresponds to a source electrode 17 of the transistor.

The outer peripheral insulating layer 2 covers an outer periphery of the front surface electrode 1. The outer peripheral insulating layer 2 insulates the front surface electrode 1 against an outer peripheral portion of the semiconductor substrate 31.

The back surface electrode 5 is disposed on a lower surface of the semiconductor substrate 31. The back surface electrode 5 is electrically connected to the transistor. The back surface electrode 5 herein corresponds to a drain electrode 18 of the transistor.

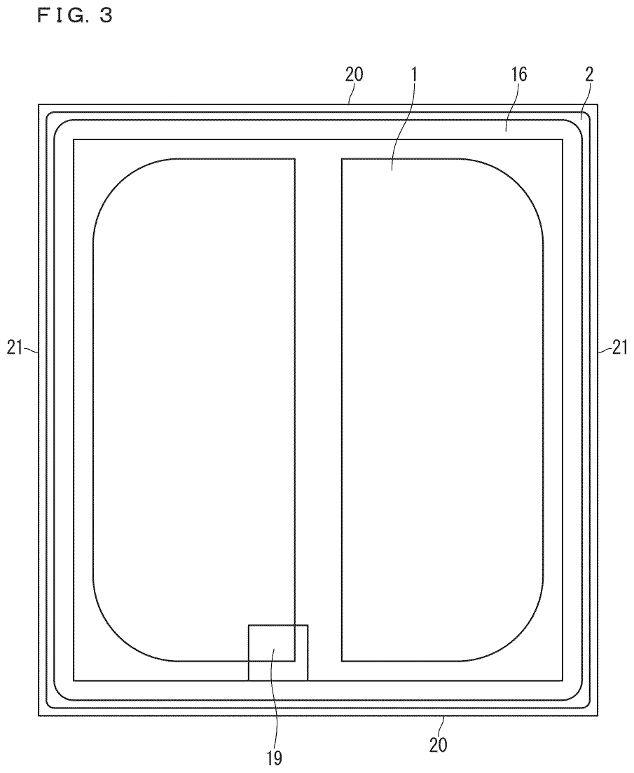

FIG. 3 is a diagram illustrating a detailed configuration on an upper surface of the semiconductor device 101. The front surface electrode 1, an interlayer dielectric film 16, a gate connecting portion 19, and the outer peripheral insulating layer 2 are arranged on the upper surface of the semiconductor device 101. The gate connecting portion 19 is electrically connected to a gate electrode (not illustrated) of the transistor. The outer peripheral insulating layer 2 covers portions of the front surface electrode 1, the gate connecting portion 19, and the interlayer dielectric film 16. The outer peripheral insulating layer 2 has an opening, and portions of the front surface electrode 1 and the gate connecting portion 19 are exposed from the opening.

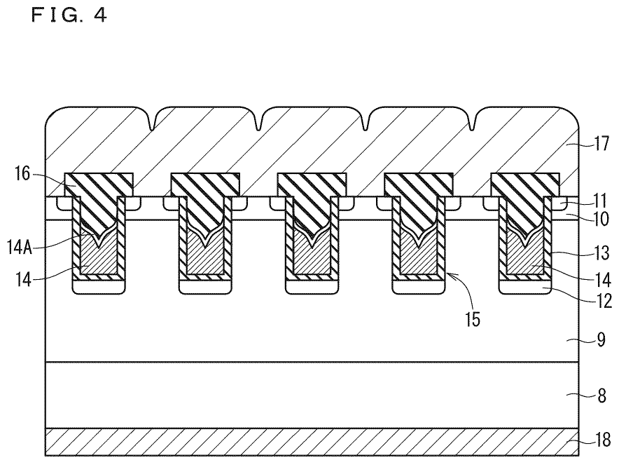

FIG. 4 is a cross-sectional view illustrating a configuration of the transistor region 6 in Embodiment 1.

The semiconductor device 101 includes, in the transistor region 6, n type source layers 11, a p type base layer 10, p type bottom base layers 12, an n type drift layer 9, an n type SiC layer 8, the trench gates 15, the interlayer dielectric film 16, the source electrode 17, and the drain electrode 18. The semiconductor substrate 31 corresponds to a range from upper surfaces of the n type source layers 11 or an upper surface of the p type base layer 10 to a lower surface of the n type SiC layer 8. The n type source layers 11, the p type base layer 10, the p type bottom base layers 12, and the n type drift layer 9 are formed of single-crystal SiC. The n type SiC layer 8 is derived from a structure of an n type SiC wafer before formation of each structure, for example. The source electrode 17 corresponds to the front surface electrode 1 in each of FIGS. 1 to 3. The drain electrode 18 corresponds to the back surface electrode 5 in each of FIGS. 1 and 2.

The trench gates 15 each include a gate dielectric film 13 and a gate electrode 14. The gate dielectric film 13 is formed along an inner wall of a trench formed from the upper surface of the semiconductor substrate 31 in a depth direction. The gate electrode 14 is formed in the trench via the gate dielectric film 13.

The interlayer dielectric film 16 is disposed over the gate electrode 14. The source electrode 17 covers the interlayer dielectric film 16, so that it can be said that the interlayer dielectric film 16 is disposed between a lower surface of the source electrode 17 and the upper surface of the semiconductor substrate 31. As illustrated in FIG. 2, the interlayer dielectric film 16 covers the breakdown voltage holding structure 7A in the termination region 7 in the outer peripheral portion of the semiconductor substrate 31.

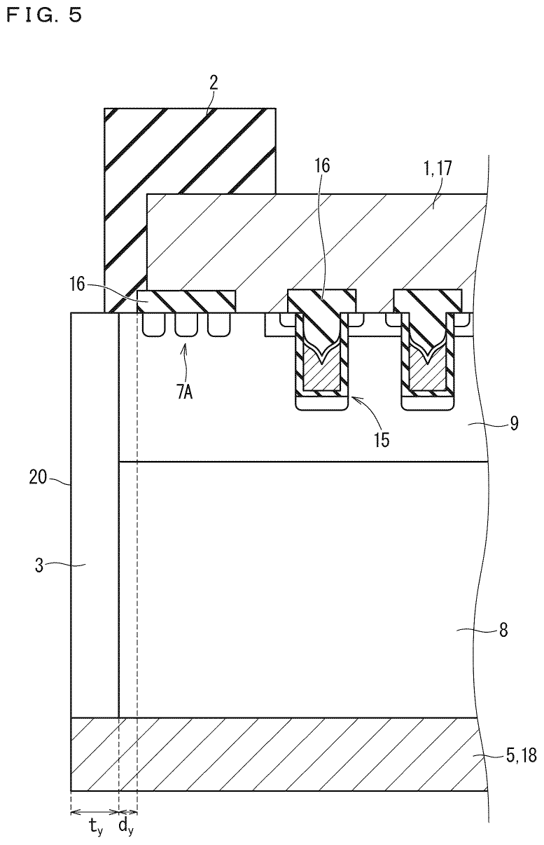

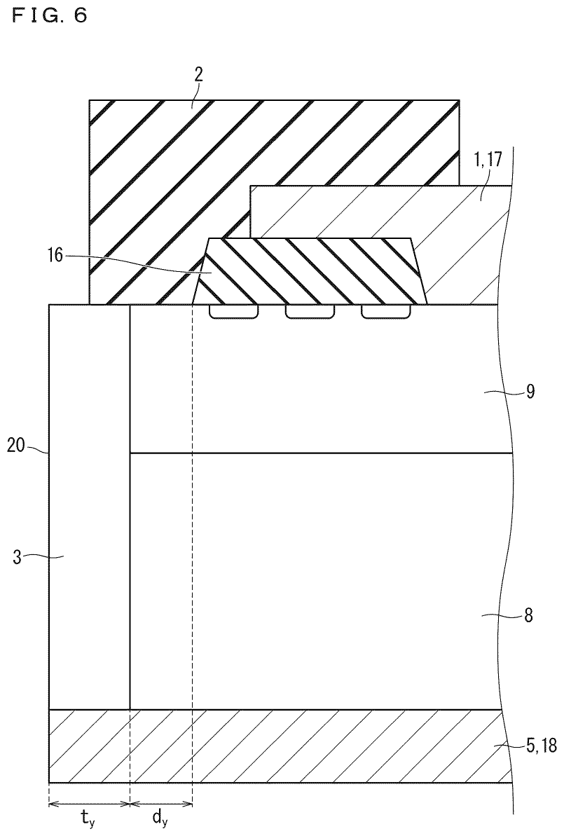

FIG. 5 is a cross-sectional view illustrating a configuration of an end portion of the semiconductor device 101. FIG. 6 is an enlarged cross-sectional view illustrating the configuration of the end portion of the semiconductor device 101. A thickness t_{y} of each of the first amorphous layers 3 corresponds to the dimension in the direction from the first side surface 20 toward the inside of the semiconductor substrate 31. Although not shown, the thickness of each of the second amorphous layers 4 similarly corresponds to the dimension in the direction from the second side surface 21 toward the inside of the semiconductor substrate 31.

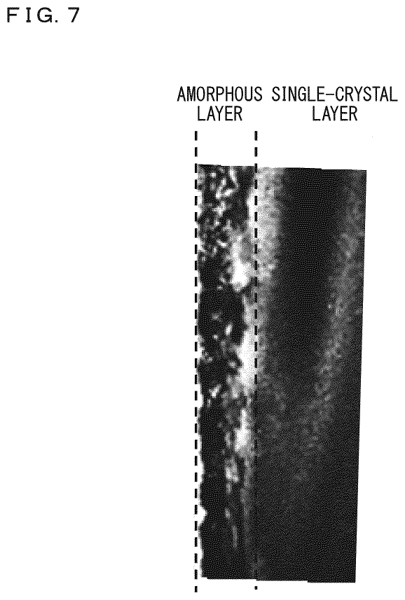

FIG. 7 is a diagram showing one example of a transmission electron microscopy (TEM) image of each of the first amorphous layers 3 in Embodiment 1. Contrast in a right region is homogeneous compared with that in a left region in the figure. The left region corresponds to each of the first amorphous layers 3, and the right region corresponds to a single-crystal layer. A thickness of the left region (a lateral dimension in the figure) is measured as the thickness of each of the first amorphous layers 3. Although not shown, a TEM image of each of the second amorphous layers 4 is similar to the TEM image shown in FIG. 7. The thickness of each of the second amorphous layers 4 is thus measured similarly to the thickness of each of the first amorphous layers 3.

The first amorphous layers 3 and the second amorphous layers 4 are formed outside the interlayer dielectric film 16 covering the termination region 7 in plan view. The first amorphous layers 3 and the second amorphous layers 4 are preferably separated from an outer edge of the interlayer dielectric film 16 by 3 μm or more. A distance d_{y} between each of the first amorphous layers 3 and the outer edge of the interlayer dielectric film 16 is defined as shown in each of FIGS. 5 and 6. For example, the distance d_{y} corresponds to a distance from an interface between each of the first amorphous layers 3 and the single-crystal layer to a perpendicular extending downward from the outer edge of the interlayer dielectric film 16. Although not shown, a distance between each of the second amorphous layers 4 and the outer edge of the interlayer dielectric film 16 is defined similarly.

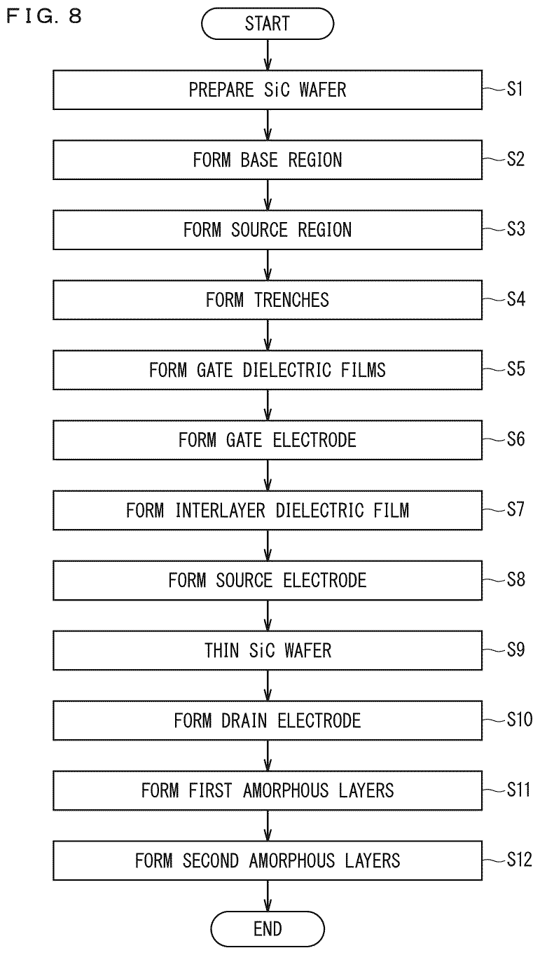

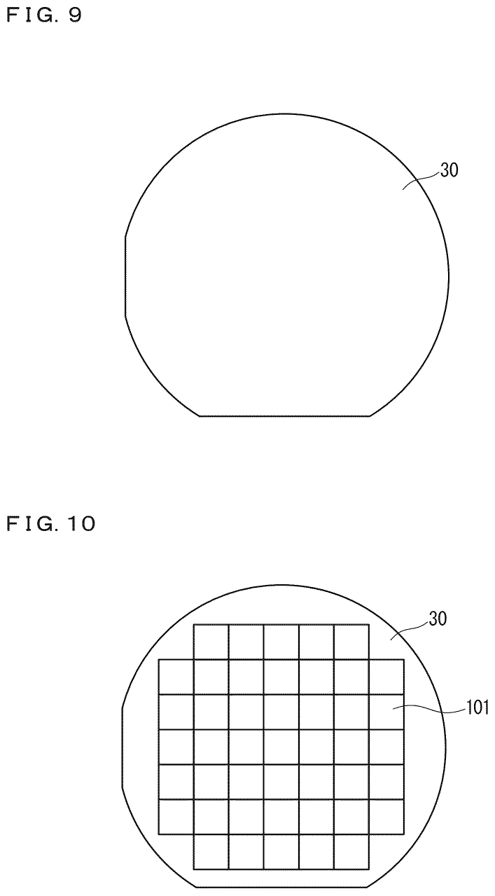

FIG. 8 is a flowchart showing steps of manufacturing the semiconductor device 101 according to Embodiment 1. FIG. 9 is a plan view illustrating a configuration of an n type SiC wafer 30. FIG. 10 is a plan view illustrating the n type SiC wafer 30 on which semiconductor devices 101 have been formed. In the manufacturing steps in Embodiment 1, a plurality of semiconductor devices are formed on a single n type SiC wafer 30. The plurality of semiconductor devices are divided individually by dicing and the like to obtain the semiconductor device 101 illustrated in each of FIGS. 1 and 2.

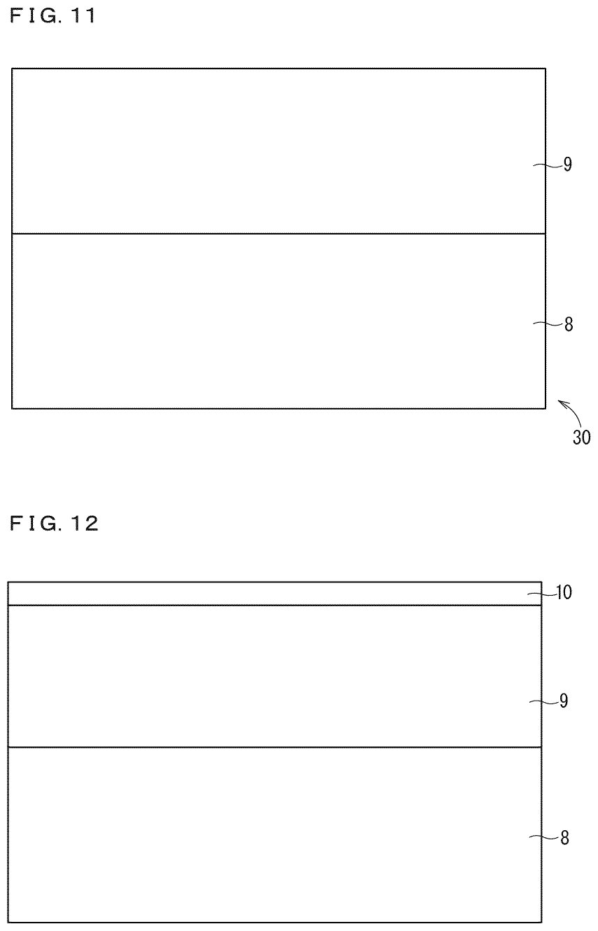

In step S1, the n type SiC wafer 30 is prepared, and the n type drift layer 9 is formed. FIG. 11 is a diagram illustrating a step of forming the n type drift layer 9 on an upper surface of the n type SiC layer 8. The n type SiC layer 8 is herein the n type SiC wafer 30 itself. The n type drift layer 9 is formed by epitaxial growth.

In step S2, the p type base layer 10 is formed. FIG. 12 is a diagram illustrating a step of forming the p type base layer 10. P type impurities are ion implanted into a predetermined region in an upper surface of the n type drift layer 9 via a mask having an opening. The mask is formed of resist and the like. The p type impurities are boron (B) or aluminum (Al), for example. In FIG. 12, the p type base layer 10 is formed in the entire surface of the n type drift layer 9.

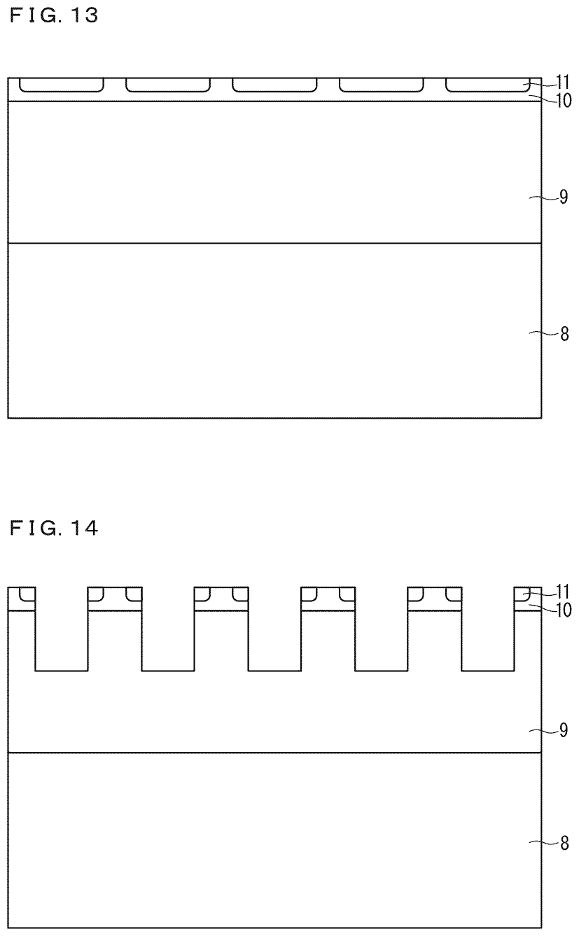

In step S3, the n type source layers 11 are formed. FIG. 13 is a diagram illustrating a step of forming the n type source layers 11. N type impurities are ion implanted into predetermined regions in an upper surface of the p type base layer via a mask having openings. The mask is formed of resist and the like. The n type impurities are phosphorus (P) or nitrogen (N), for example. After ion implantation, the SiC wafer 30 is heat treated at a high temperature. Due to heat treatment, the p type impurities implanted into the p type base layer 10 and the n type impurities implanted into the n type source layers 11 are electrically activated.

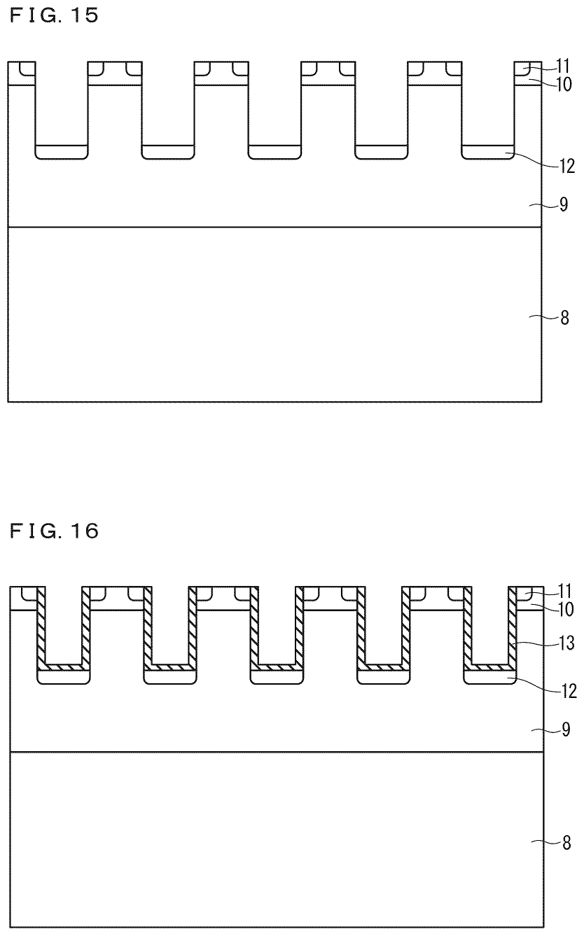

In step S4, trenches are formed. FIG. 14 is a diagram illustrating a step of forming the trenches. A mask having openings is formed in a predetermined region on the upper surface of the p type base layer 10 and the upper surfaces of the n type source layers 11. The mask is formed of resist and the like, for example. The trenches are then formed by dry etching using plasma and the like. The mask may be a TEOS-based oxidation film, and, in this case, deeper trenches are formed. After formation of the trenches, the p type bottom base layers 12 are formed at bottoms of the trenches. FIG. 15 is a diagram illustrating a step of forming the p type bottom base layers 12. The p type bottom base layers 12 are formed by ion implantation of the p type impurities. The p type impurities are boron (B) or aluminum (Al), for example. The p type bottom base layers 12 relieve electric field concentration at the bottoms of the trenches.

In step S5, gate dielectric films 13 are formed. FIG. 16 is a diagram illustrating a step of forming the gate dielectric films 13. The gate dielectric films 13 are formed by thermal oxidation to remove plasma damage when the trench gates 15 are formed. In other words, the gate dielectric films 13 are formed by oxidation of the n type drift layer 9 at inner walls of the trenches. A gate oxidation film has a thickness of 20 nm or more and 80 nm or less and more preferably has a thickness of 30 nm or more and 70 nm or less. A thickness of each of the gate dielectric films 13 in a side surface of a trench is equivalent to or greater than a thickness of the gate dielectric film 13 at a bottom of the trench. The thickness of each of the gate dielectric films 13 in the side surface of the trench is preferably 10% or more greater than the thickness of the gate dielectric film 13 at the bottom of the trench. The gate dielectric films 13 may be formed by chemical vapor deposition (CVD).

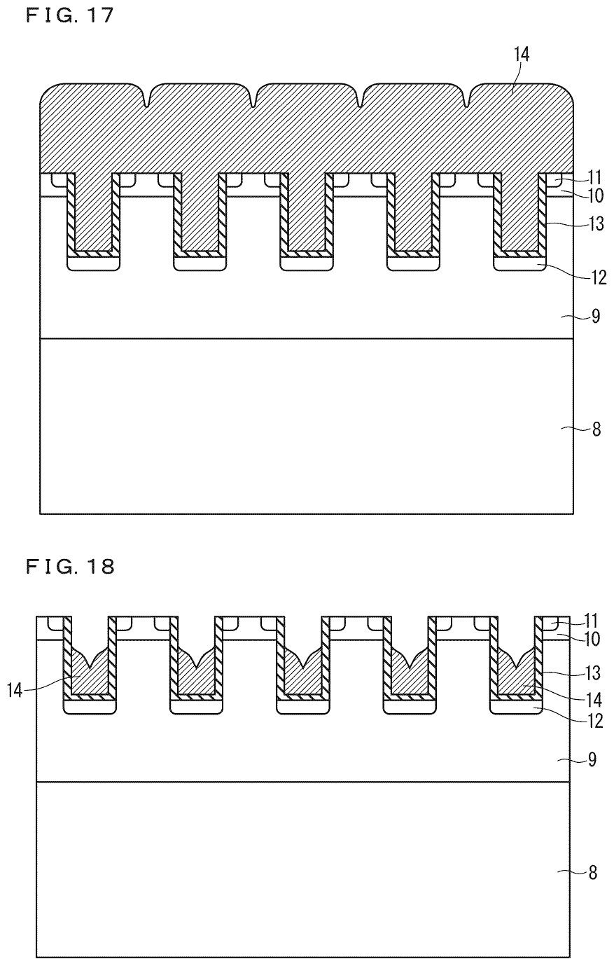

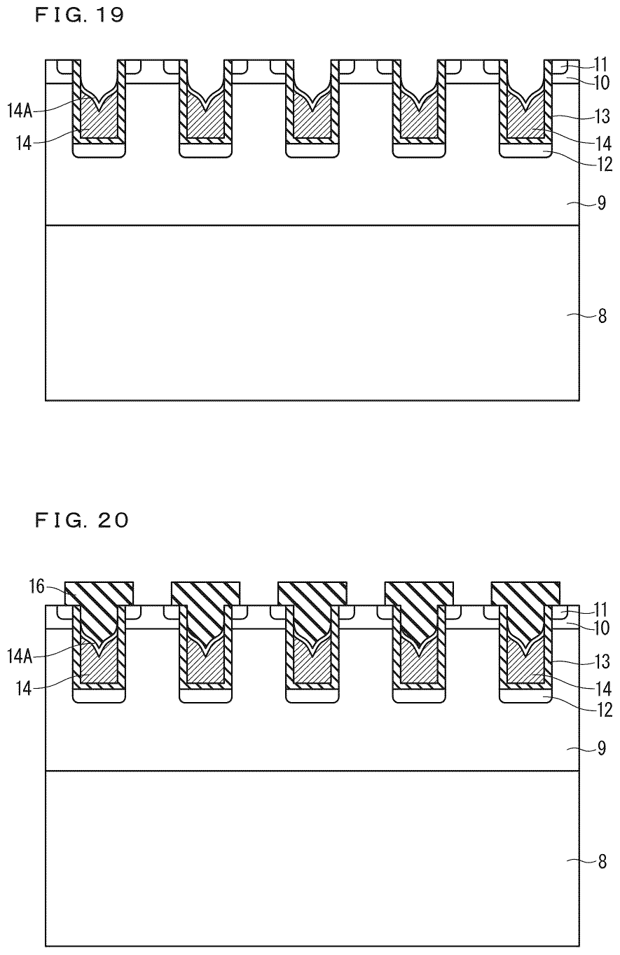

In step S6, the gate electrode 14 is formed. FIG. 17 is a diagram illustrating a step of forming the gate electrode 14. FIG. 18 is a diagram illustrating a step of removing an excess portion of the gate electrode 14. The gate electrode 14 is formed of polysilicon, for example. After the gate electrode 14 is formed on the gate dielectric films 13, the excess portion of the gate electrode 14 is removed by etching. Etching is preferably isotropic etching. Etching is dry etching using plasma containing SF₆ or wet etching using mixed acid containing hydrofluoric acid and nitric acid, for example. An oxidation layer 14A is then formed on a surface of the gate electrode 14 by thermal oxidation. FIG. 19 is a diagram illustrating a step of forming the oxidation layer 14A. An oxidation temperature is 850° C. or more and 1050° C. or less and is more preferably 900° C. or more and 1000° or less. A thickness of the oxidation layer 14A is 10 nm or more and 40 nm or less and is more preferably 20 nm or more and 35 nm or less.

In step S7, the interlayer dielectric film 16 is formed. FIG. 20 is a diagram illustrating a step of forming the interlayer dielectric film 16. The interlayer dielectric film 16 is formed using CVD and is patterned by photolithography and etching after formation. Impurities such as B (boron), P (phosphorus), and the like may be introduced into the interlayer dielectric film 16. Due to introduction of the impurities, corners of the interlayer dielectric film 16 are rounded. The interlayer dielectric film 16 is formed of silicon nitride (SiₓN_{y}) or silicon oxide (SiO₂), for example. The interlayer dielectric film 16 preferably has a thickness of 0. 5 μm or more and 2.0 μm or less.

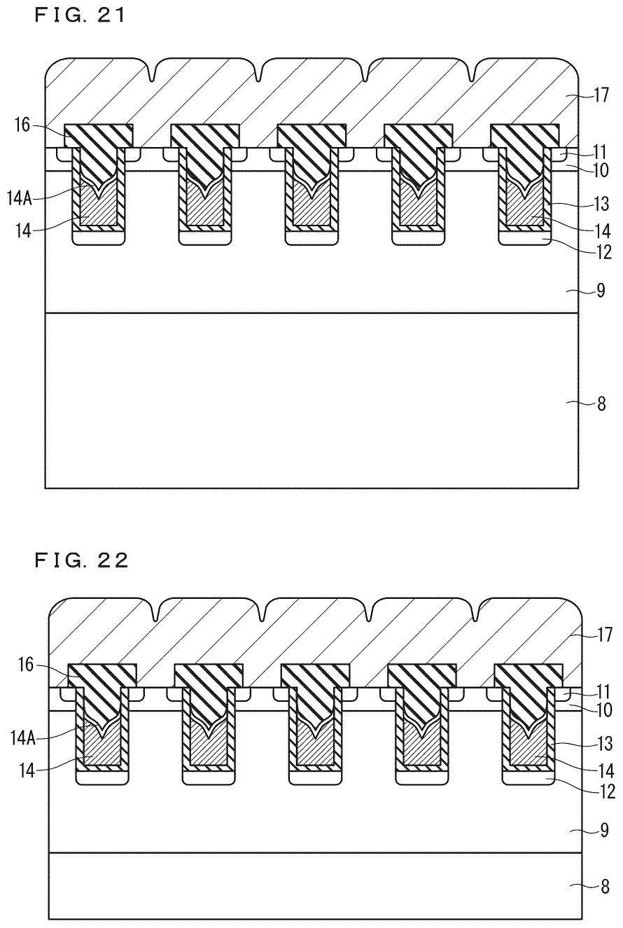

In step S8, the source electrode 17 is formed. FIG. 21 is a diagram illustrating a step of forming the source electrode 17. The source electrode 17 is formed of aluminum, nickel, an aluminum alloy, and the like. The aluminum alloy contains aluminum and silicon. A barrier metal may be interposed between the source electrode 17 and the p type base layer 10 and between the source electrode 17 and the n type source layers 11. The barrier metal is formed of titanium or a titanium compound such as titanium nitride (TiN). After formation of the source electrode 17, the outer peripheral insulating layer 2 as illustrated in FIG. 2 is formed. The outer peripheral insulating layer 2 is formed of a polyimide resin or a silicone resin, for example. The outer peripheral insulating layer 2 is preferably formed using photolithography technology to form a desired shape with high accuracy. Furthermore, etching technology may be used concurrently. A method of forming the outer peripheral insulating layer 2 is not limited to the foregoing, and screen printing technology or drawing application technology may be used.

In step S9, the SiC wafer 30 is thinned, that is to say, the n type SiC layer 8 is thinned. FIG. 22 is a diagram illustrating a step of thinning the n type SiC layer 8. A lower surface of the SiC wafer 30, that is, the lower surface of the n type SiC layer 8 is ground by machining using a grinding wheel.

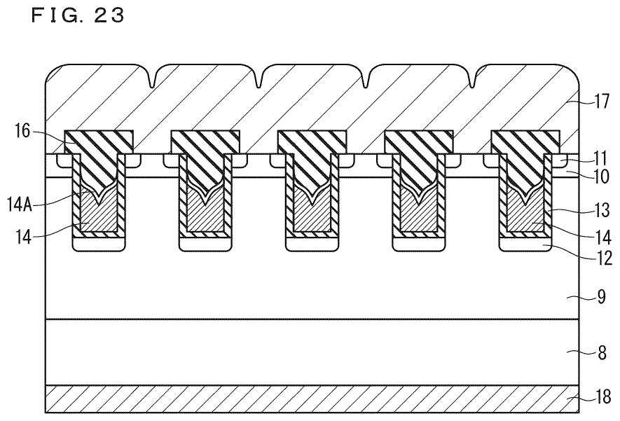

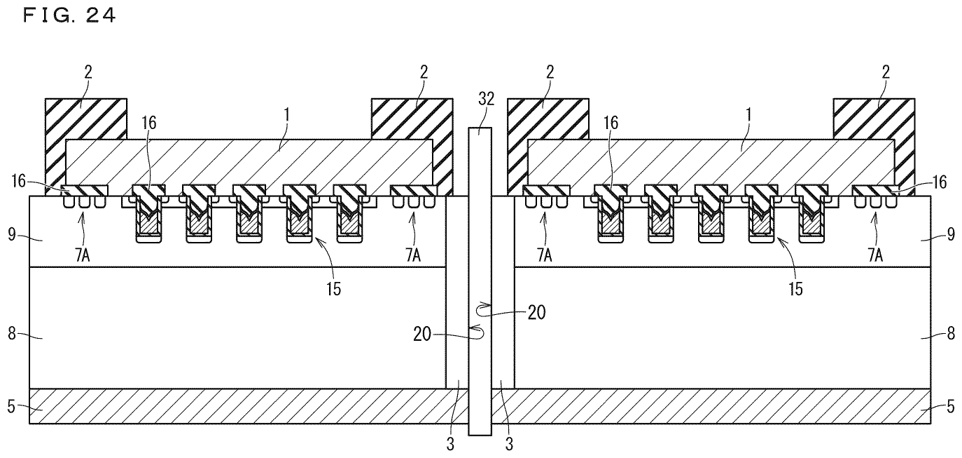

In step S10, the drain electrode 18 is formed. FIG. 23 is a diagram illustrating a step of forming the drain electrode 18. The drain electrode 18 is formed by sputtering, for example. The drain electrode 18 is a nickel film, for example. The drain electrode 18 has a thickness of approximately 600 nm, for example. The drain electrode 18 may be a stack of a nickel film and a metal film having poor reactivity to an outside. The stack prevents oxidation of a surface of nickel. Metal having poor reactivity to the outside is gold or silver. Wettability of a solder alloy with the nickel film is improved to obtain good joining.

The plurality of semiconductor devices are formed on the single SiC wafer 30 in steps S1 to S10 described above. The plurality of semiconductor devices are divided into individual semiconductor devices 101 in steps S11 and S12 below. In this case, the first amorphous layers 3 and the second amorphous layers 4 are formed.

In step S11, the first amorphous layers 3 are formed. FIG. 24 is a diagram illustrating a step of forming the first amorphous layers 3. The plurality of semiconductor devices formed on the SiC wafer 30 are divided into the individual semiconductor devices 101 by dicing. The first amorphous layers 3 are formed when the SiC wafer 30 is diced along a longitudinal direction of the trench gates 15. More specifically, a blade 32 used for dicing cuts the drain electrode 18, the n type SiC layer 8, and the n type drift layer 9. In this case, the first amorphous layers 3 are formed by friction of the blade 32 with each semiconductor layer. In other words, the blade 32 rubs each semiconductor layer to alter a single crystal forming each semiconductor layer. For example, compressive stress or tensile stress is produced between the single crystal and abrasive grains contained in the blade 32 during dicing. Heat generated by stress alters the single crystal into an amorphous form. In particular, a portion of contact between the blade 32 and each semiconductor layer generates heat to form the first amorphous layers 3 in the first side surfaces 20 of the semiconductor substrate 31.

The blade 32 is an electroformed blade, for example, but is not limited to the electroformed blade. A blade containing abrasive grains each having a desired diameter can be selected as appropriate. A blade rotational speed is 10,000 rpm or more and 30,000 rpm or less. A blade feed speed is 5 μmm/see or more and 100 μmm/see or less. The blade rotational speed and the blade feed speed are adjusted as appropriate responsive to a blade material and a dicing apparatus. In Embodiment 1, the blade rotational speed is 20,000 rpm, and the blade feed speed is 20 μmm/sec.

In step S12, the second amorphous layers 4 are formed. The second amorphous layers 4 are formed when the SiC wafer 30 is diced along a transverse direction of the trench gates 15. In Embodiment 1, a dicing condition in step S12 is different from a dicing condition in step S11. The thickness of each of the second amorphous layers 4 is thus different from the thickness of each of the first amorphous layers 3. For example, a thickness of an amorphous layer increases with increasing size of each of the abrasive grains contained in the blade 32. The thickness of the amorphous layer decreases with decreasing size of each of the abrasive grains contained in the blade 32.

Amorphous layers are formed in four side surfaces of the semiconductor substrate 31 in steps S11 and S12 described above.

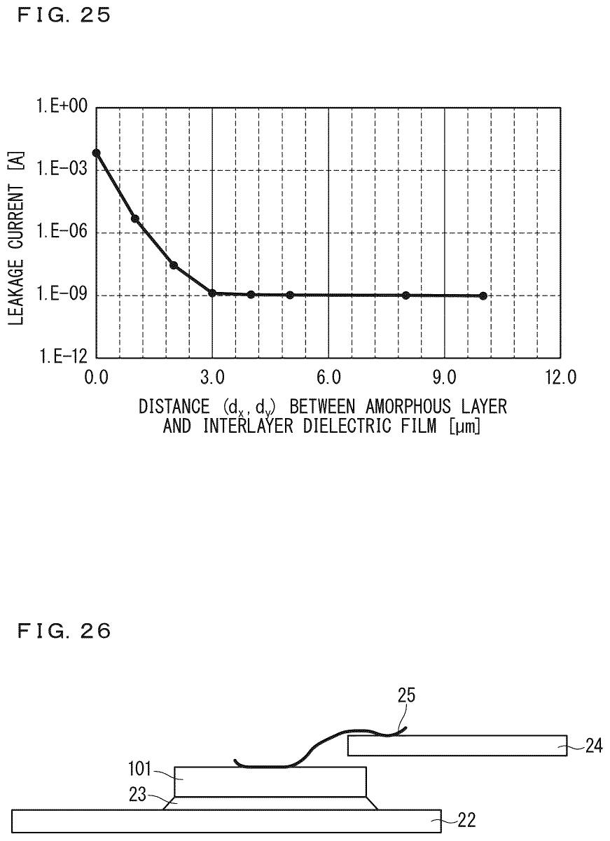

FIG. 25 is a diagram showing a relationship between a distance between the amorphous layer and the interlayer dielectric film 16 and a source-drain leakage current. A gate voltage is −15 V. A voltage of 1200 V is applied across a source and a drain as a rated voltage. In a horizontal axis in FIG. 25, a distance dx indicates a distance between each of the second amorphous layers 4 and the interlayer dielectric film 16, and a distance d_{y} indicates a distance between each of the first amorphous layers 3 and the interlayer dielectric film 16. The source-drain leakage current is reduced in a case where the distance between the amorphous layer and the interlayer dielectric film 16 is 3 μm or more. The gate voltage at which the transistor is off is not limited to −15 V. The gate voltage is set to any voltage, such as −5 V and 0 V. The voltage applied across the source and the drain is not limited to 1200 V. A similar result is obtained even when a voltage in a range from 600 V to 6500 V is applied across the source and the drain as long as an impurity concentration of the n type drift layer 9 is set appropriately. That is to say, the source-drain leakage current is reduced in a case where the distance between the amorphous layer and the interlayer dielectric film 16 is 3 μm or more.

FIG. 26 is a diagram illustrating the semiconductor device 101 mounted to leads. The back surface electrode 5 (not illustrated in FIG. 26) of the semiconductor device 101 is connected to a first lead 22 via solder 23. The front surface electrode 1 (not illustrated in FIG. 26) of the semiconductor device 101 is connected to a second lead 24 via a wire 25. Each of the first lead 22 and the second lead 24 has a plate-like shape and is formed of metal. Although not illustrated, the gate connecting portion 19 is similarly connected to an appropriate lead by a wire. The semiconductor device 101 mounted as described above was subjected to a switching test of ten thousand cycles under a 150° C. environment.

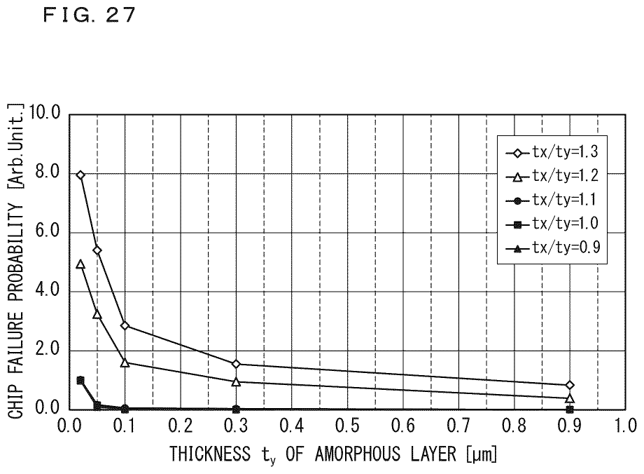

FIG. 27 is a diagram showing a relationship between the thickness t_{y} of each of the first amorphous layers 3 and chip failure probability. FIG. 27 shows results of the switching test conducted on semiconductor devices 101 having five types of ratios of a thickness tₓ of each of the second amorphous layers 4 to the thickness t_{y} of each of the first amorphous layers 3 ranging from 0.9 to 1.3. The chip failure probability is normalized to a value in a case where the thickness t_{y} of each of the first amorphous layers 3 is 0.02 μm, and a ratio tₓ/t_{y} of the thicknesses of the two amorphous layers is 1.0. The chip failure probability after switching is significantly reduced in a case where the thickness t_{y} of each of the first amorphous layers 3 is 0.05 μm or more and the ratio tₓ/t_{y} of the thicknesses of the two amorphous layers is 1.1 or less.

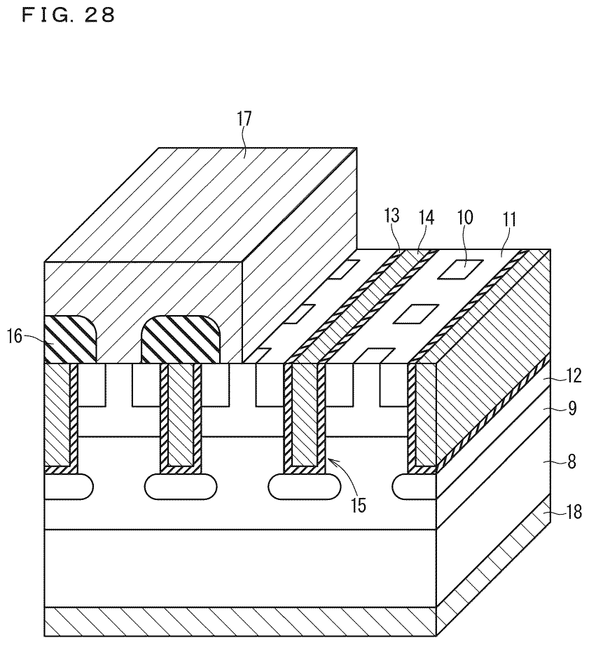

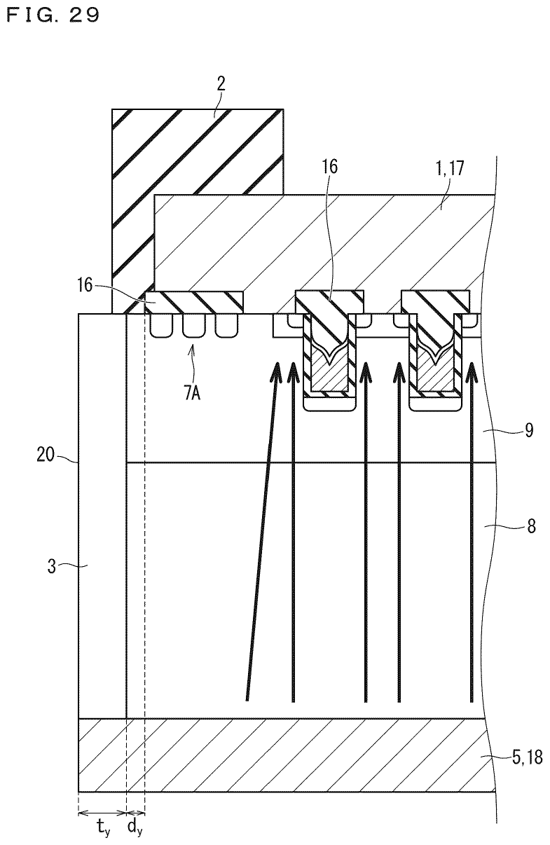

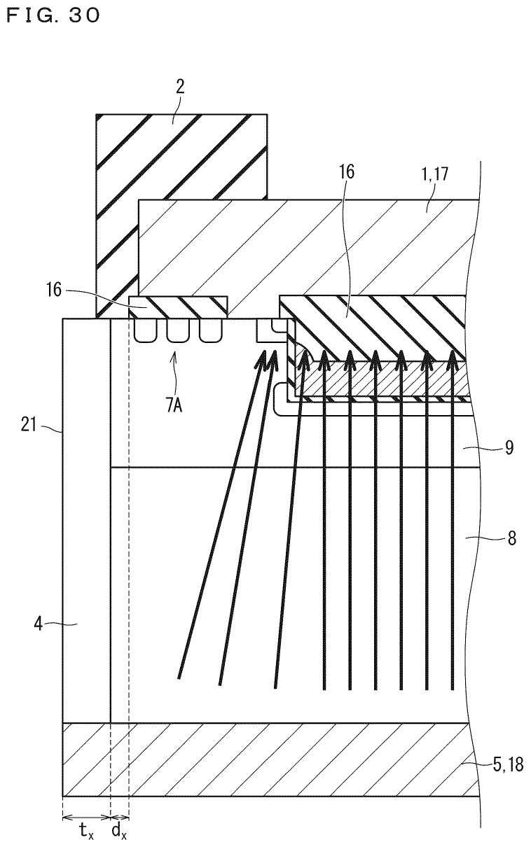

FIG. 28 is a bird's eye view schematically showing a configuration of an inside of the semiconductor device 101 according to Embodiment 1. FIG. 29 is a diagram illustrating the configuration of the semiconductor device 101 in a cross section orthogonal to the direction of extension of the trench gates 15. FIG. 29 corresponds to a cross section of an end portion of the semiconductor device 101 as viewed from a front side in FIG. 28. The thickness t_{y} of each of the first amorphous layers 3 and the distance d_{y} between each of the first amorphous layers 3 and the interlayer dielectric film 16 are shown in FIG. 29. Furthermore, current flow in a case where the semiconductor device 101 is on is schematically shown by arrows in FIG. 29. Channels are formed near the trench gates 15, so that a current path does not expand.

FIG. 30 is a diagram illustrating the configuration of the semiconductor device 101 in a cross section parallel to the direction of extension of the trench gates 15. FIG. 30 corresponds to a cross section of the end portion of the semiconductor device 101 as viewed from a right side in FIG. 28. The thickness tₓ of each of the second amorphous layers 4 and the distance dx between each of the second amorphous layers 4 and the interlayer dielectric film 16 are shown in FIG. 30. Furthermore, current flow in a case where the semiconductor device 101 is on is schematically shown by arrows in FIG. 30. The channels are formed near the trench gates 15, but a current flows to expand in the end portion of the trench gates 15. That is to say, portions around the trench gates 15 are portions of the current path. In a case where a ratio of the thickness tₓ of each of the second amorphous layers 4 to the thickness t_{y} of each of the first amorphous layers 3 is 1.1 or less, a current flowing through an amorphous layer having a higher electrical resistance than the single crystal is reduced, and chip failure is prevented.

Taken together, the semiconductor device 101 according to Embodiment 1 includes the semiconductor substrate 31, the trench gates 15, the first amorphous layers 3, and the second amorphous layers 4. The semiconductor substrate 31 includes a semiconductor element being at least one of a transistor and a diode. The trench gates 15 each include an electrode to control a state of the semiconductor element. The trench gates 15 are provided in the upper surface of the semiconductor substrate 31. The first amorphous layers 3 are disposed in the first side surfaces 20 of the semiconductor substrate 31. The second amorphous layers 4 are disposed in the second side surfaces 21 of the semiconductor substrate 31. In plan view, a first angle between each of the first side surfaces 20 and a direction of extension of the trench gates 15 is smaller than a second angle between each of the second side surfaces 21 and the direction of extension of the trench gates 15, or the first side surfaces 20 are parallel to the direction of extension of the trench gates 15. The thickness of each of the first amorphous layers 3 in the direction from the first side surface 20 toward the inside of the semiconductor substrate 31 is different from the thickness of each of the second amorphous layers 4 in the direction from the second side surface 21 toward the inside of the semiconductor substrate 31.

The semiconductor device 101 having such a configuration reduces current concentration on an outer peripheral portion of the semiconductor device 101 when switching operation is performed. Reliability of the semiconductor device 101 is thus improved.

The semiconductor device 101 is a semiconductor device for power control (so-called power semiconductor device), for example. The semiconductor device 101 controls a current flowing between the front surface electrode 1 and the back surface electrode 5. The semiconductor element included in the semiconductor device 101 is not limited to a metal oxide semiconductor field effect transistor (MOSFET). The semiconductor element is only required to be a semiconductor element including the trench gates 15 and may be an insulated gate bipolar transistor (IGBT), a Schottky barrier diode, and the like, for example. The semiconductor device 101 may be a reverse-conducting IGBT (an RC-IGBT), which includes an IGBT and a freewheeling diode formed in a single semiconductor substrate 31.

In Embodiment 1, the first side surfaces 20 and the second side surfaces 21 are defined by the direction of extension of the trench gates 15. The trench gates 15 are not limited to trench gates 15 constituting a MOSFET. That is to say, the trench gates 15 defining the first side surfaces 20 and the second side surfaces 21 may be trench gates constituting a semiconductor element such as an IGBT and a freewheeling diode.

The semiconductor substrate 31 is preferably formed of a wide bandgap semiconductor. For example, SiC has a higher breakdown voltage and a higher thermal resistance than Si and thus allows for an increase in breakdown voltage, reduction in loss, use under a high temperature environment, and the like of the semiconductor device 101. The semiconductor device 101 formed of SiC is suitable for a part forming an inverter.

The first side surfaces 20 of the semiconductor substrate 31 are not required to be parallel to the direction of extension of the trench gates 15. Similarly, the second side surfaces 21 of the semiconductor substrate 31 are not required to be orthogonal to the direction of extension of the trench gates 15. In plan view, the first angle between each of the first side surfaces 20 and the direction of extension of the trench gates 15 is only required to be smaller than the second angle between each of the second side surfaces 21 and the direction of extension of the trench gates 15.

In a case where the semiconductor substrate 31 is formed of a hexagonal material such as SiC, a crystal plane in each of the first side surfaces 20 of the semiconductor device 101 is not equivalent to a crystal plane in each of the second side surfaces 21 of the semiconductor device 101. In this case, even in a case where the second side surfaces 21 are obtained by dicing under the same dicing condition as the dicing condition for the first side surfaces 20, the first amorphous layers 3 and the second amorphous layers 4 differing in thickness are self-formed. That is to say, in a case where the semiconductor substrate 31 is formed of the hexagonal material such as SiC, the dicing condition in step S12 is not necessarily required to be different from the dicing condition in step S11.

While five trench gates 15 are illustrated in each of FIGS. 2 and 4, the number of trench gates 15 is not limited to five. Any number of trench gates 15 may be arranged discretely in a left-right direction in FIG. 4.

### Embodiment 2

In Embodiment 2, similar components to those in Embodiment 1 bear the same reference signs as those of the similar components, and detailed description thereof will be omitted.

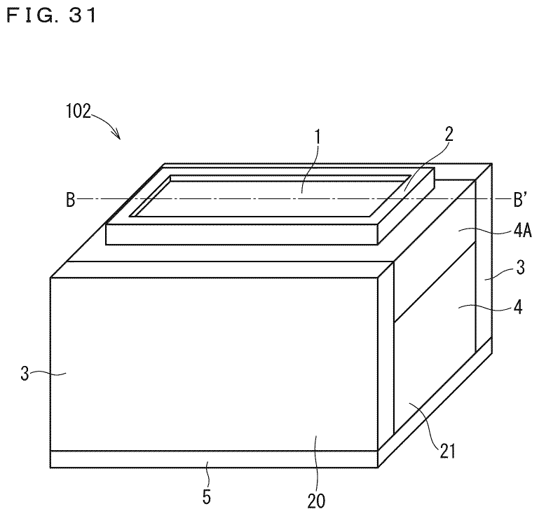

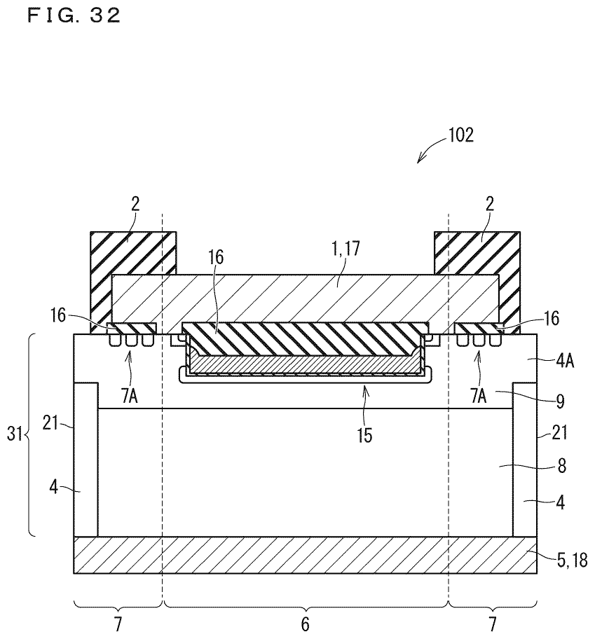

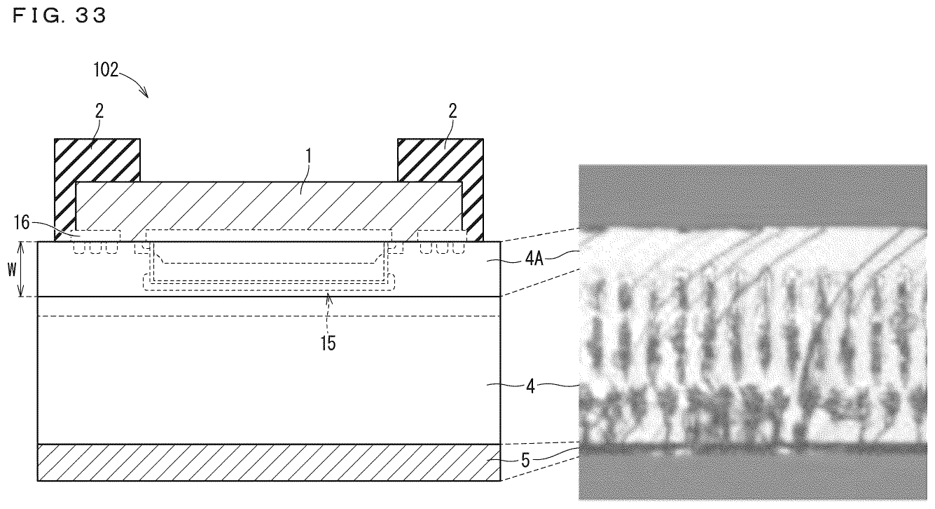

FIG. 31 is a perspective view illustrating a configuration of a semiconductor device 102 according to Embodiment 2. FIG. 32 is a cross-sectional view taken along the line B-B′ of FIG. 31.

The semiconductor device 102 includes the semiconductor substrate 31, the transistor region 6, the trench gates 15, the termination region 7, the front surface electrode 1, the outer peripheral insulating layer 2, the back surface electrode 5, the first amorphous layers 3, the second amorphous layers 4, and single-crystal layers 4A. The semiconductor device 102 according to Embodiment 2 is different from the semiconductor device 101 according to Embodiment 1 in that the single-crystal layers 4A are included.

The second amorphous layers 4 are formed in lower portions of the second side surfaces 21. Specifically, the second amorphous layers 4 are formed in lower portions of side surfaces of the n type drift layer 9 and in side surfaces of the n type SiC layer 8. In other words, the second amorphous layers 4 do not reach the upper surface of the semiconductor substrate 31 in the second side surfaces 21.

The single-crystal layers 4A are formed in upper portions of the second side surfaces 21. Specifically, the single-crystal layers 4A are formed in upper portions of the side surfaces of the n type drift layer 9. In other words, the single-crystal layers 4A are arranged above the second amorphous layers 4. The single-crystal layers 4A are herein formed of SiC forming the n type drift layer 9.

The single-crystal layers 4A are not arranged below interfaces between the second amorphous layers 4 and the single-crystal layers 4A in the second side surfaces 21. Only the second amorphous layers 4 are arranged below the interfaces between the second amorphous layers 4 and the single-crystal layers 4A. The second amorphous layers 4 are not arranged above the interfaces between the second amorphous layers 4 and the single-crystal layers 4A in the second side surfaces 21. Only the single-crystal layers 4A are arranged above the interfaces between the second amorphous layers 4 and the single-crystal layers 4A.

A method of manufacturing the semiconductor device 102 according to Embodiment 2 will be described. Steps S1 to S11 are similar to those in Embodiment 1.

In step S12, laser light is emitted along a dicing line extending in the transverse direction of the trench gates 15. The laser light has a wavelength in a near-ultraviolet region to a visible light region. The wavelength is 380 nm, for example. In this case, the laser light is focused on a lower portion of the n type drift layer 9 and the n type SiC layer 8. Due to the laser light, the single crystal is altered into the amorphous form to form the second amorphous layers 4. In Embodiment 2, the laser light is emitted three times, and a processing speed is 500 μmm/sec. The semiconductor substrate 31 to be processed has a thickness of approximately 100 μm. After laser emission, stress is applied to the SiC wafer 30, so that division of the SiC wafer 30 originates from the second amorphous layers 4. As a result, the plurality of semiconductor devices formed on the single SiC wafer 30 are divided into the individual semiconductor devices 102.

FIG. 33 is a diagram showing a correspondence between a second side surface 21 of the semiconductor device 102 shown schematically and an optical microscope image of the second side surface 21. In the optical microscope image, a second amorphous layer 4 is formed in a lower portion of the second side surface 21, and a single-crystal layer 4A is formed in an upper portion of the second side surface 21. A width w of the single-crystal layer 4A is shown in FIG. 33.

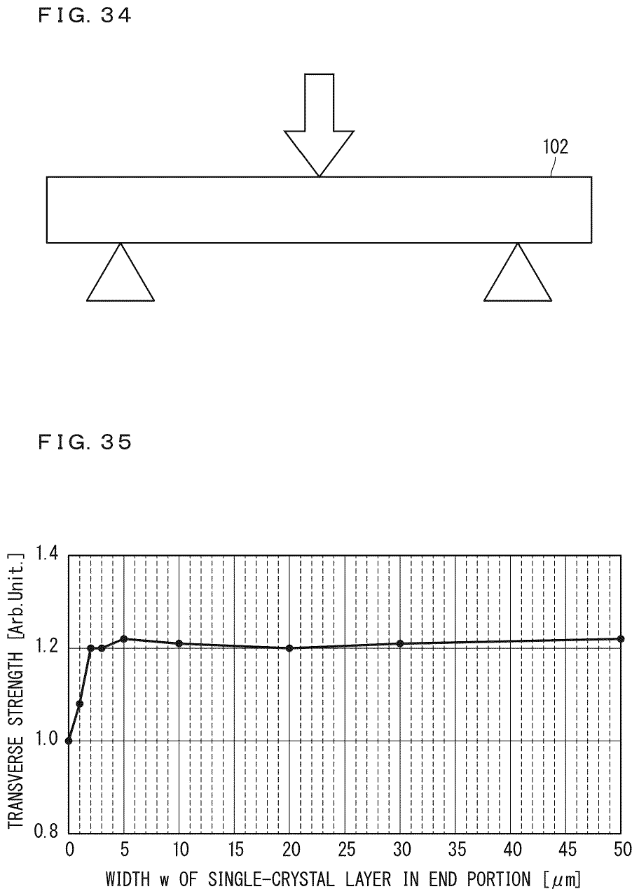

FIG. 34 is a schematic diagram illustrating the semiconductor device 102 according to Embodiment 2 undergoing a three-point bending test. The longitudinal direction of the trench gates 15 corresponds to a left-right direction in FIG. 34. A support span is 8 μmm. An indenter above the semiconductor device 102 is lowered toward the semiconductor device 102 at a speed of 0.5 μmm/min. A transverse strength was calculated based on the amount of deflection and a breaking load in this case.

FIG. 35 is a diagram showing a relationship between the width w of the single-crystal layer 4A in the second side surface 21 and the transverse strength of the semiconductor device 102. The transverse strength is normalized to a value in a case where the width w of the single-crystal layer 4A is 0 μm. In a case where the width w of the single-crystal layer 4A is 2 μm or more, a mechanical strength of the semiconductor device 102 is improved.

Chip failure probability in Embodiment 2 is similar to that in the results shown in FIG. 27. A path of a current flowing from a back surface to a front surface of the semiconductor device 102 does not expand to an outer peripheral portion of the semiconductor device 102 as in each of FIGS. 29 and 30. The single-crystal layers 4A formed in the second side surfaces 21 thus do not induce chip failure. As described above, the semiconductor device 102 according to Embodiment 2 has an enhanced chip strength while preventing breakage caused by switching operation. That is to say, the semiconductor device 102 has not only improved reliability but also an enhanced mechanical strength.

In Embodiment 2, after the first amorphous layers 3 are formed using the blade 32, the second amorphous layers 4 are formed using a laser. In a case where the second amorphous layers 4 are formed first using the laser, and then the first amorphous layers 3 are formed using the blade 32, chipping of the plurality of semiconductor devices originates from the second amorphous layers 4 due to stress applied from the blade 32. The second amorphous layers 4 are thus preferably formed using the laser after formation of the first amorphous layers 3 using the blade 32.

While a single continuous trench gate 15 is illustrated in FIG. 32, a configuration of each of the trench gates 15 is not limited to this configuration. Two trench gates obtained by division at the center of the transistor region 6 may be arranged. Any number of trench gates obtained by division may be arranged discretely in a left-right direction in FIG. 32.

### Embodiment 3

In Embodiment 3, similar components to those in Embodiment 1 and Embodiment 2 bear the same reference signs as those of the similar components, and detailed description thereof will be omitted.

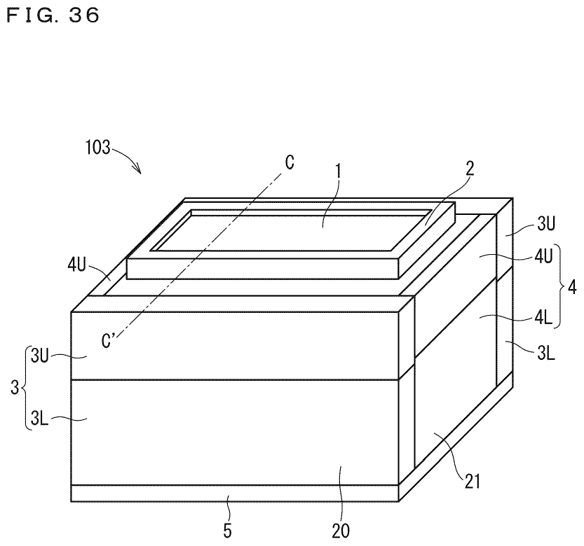

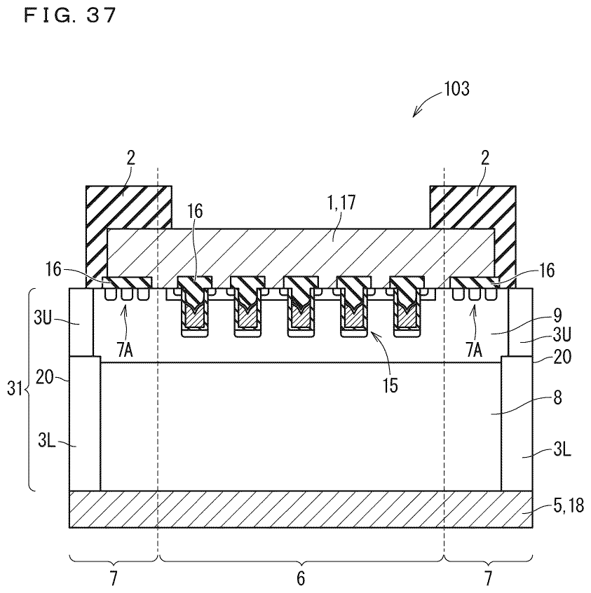

FIG. 36 is a perspective view illustrating a configuration of a semiconductor device 103 according to Embodiment 3. FIG. 37 is a cross-sectional view taken along the line C-C′ of FIG. 36.

The semiconductor device 103 includes the semiconductor substrate 31, the transistor region 6, the trench gates 15, the termination region 7, the front surface electrode 1, the outer peripheral insulating layer 2, the back surface electrode 5, lower first amorphous layers 3L, upper first amorphous layers 3U, lower second amorphous layers 4L, and upper second amorphous layers 4U. The semiconductor device 103 according to Embodiment 3 is different from the semiconductor device 101 according to Embodiment 1 in that the first amorphous layers 3 include the lower first amorphous layers 3L and the upper first amorphous layers 3U and the second amorphous layers 4 include the lower second amorphous layers 4L and the upper second amorphous layers 4U. In other words, thicknesses of the first amorphous layers 3 and thicknesses of the second amorphous layers 4 in side surfaces of the semiconductor device 103 each differ between an upper portion and a lower portion of the semiconductor device 103.

The upper first amorphous layers 3U are formed in upper portions of the first amorphous layers 3 in the first side surfaces 20. Specifically, the upper first amorphous layers 3U are formed in the side surfaces of the n type drift layer 9. The lower first amorphous layers 3L are formed in the side surfaces of the n type drift layer 9 and the n type SiC layer 8, that is, formed closer to a lower surface of the semiconductor device 103 to be connected to the upper first amorphous layers 3U.

The upper second amorphous layers 4U are formed in upper portions of the second amorphous layers 4 in the second side surfaces 21. Specifically, the upper second amorphous layers 4U are formed in the side surfaces of the n type drift layer 9. The lower second amorphous layers 4L are formed in the side surfaces of the n type drift layer 9 and the n type SiC layer 8, that is, formed closer to the lower surface of the semiconductor device 103 to be connected to the upper second amorphous layers 4U.

As illustrated in FIG. 36, boundaries between the upper first amorphous layers 3U and the lower first amorphous layers 3L and boundaries between the upper second amorphous layers 4U and the lower second amorphous layers 4L are not necessarily required to be at the same level.

A method of manufacturing the semiconductor device 103 according to Embodiment 3 will be described. Steps S1 to S10 are similar to those in Embodiment 1, but steps S11 and S12 are different from those in Embodiment 1.

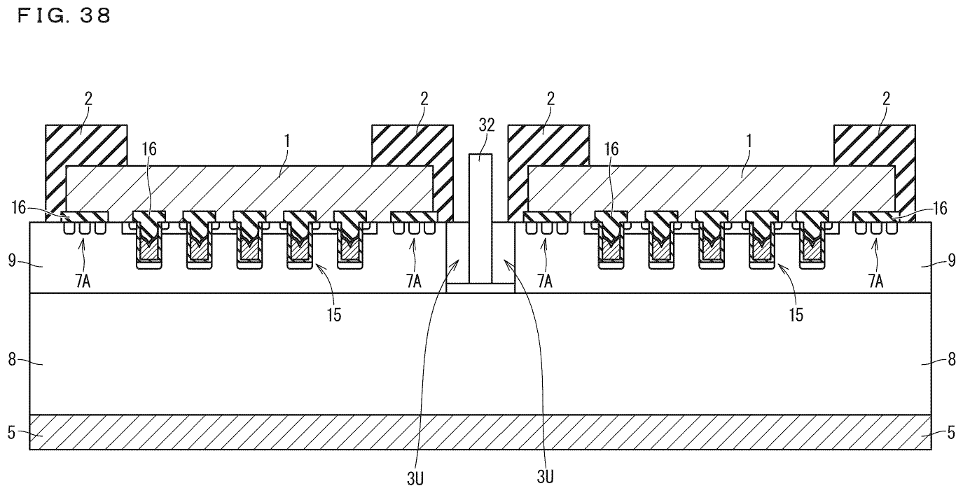

In step S11, the upper first amorphous layers 3U and the lower first amorphous layers 3L are formed. FIG. 38 is a diagram illustrating a step of forming the upper first amorphous layers 3U. The plurality of semiconductor devices formed on the SiC wafer 30 are divided into individual semiconductor devices 103 by dicing. The upper first amorphous layers 3U are formed when the SiC wafer 30 is diced along the longitudinal direction of the trench gates 15. More specifically, the blade 32 used for dicing cuts at least portion of the n type drift layer 9. In this case, the upper first amorphous layers 3U are formed by friction of the blade 32 with the n type drift layer 9. The lower first amorphous layers 3L are then formed on remaining portions of the n type drift layer 9 and the n type SiC layer 8, and the drain electrode 18 is cut.

For example, the thickness of the amorphous layer increases with increasing size of each of the abrasive grains contained in the blade 32. The upper first amorphous layers 3U can thus be thinner than the lower first amorphous layers 3L by causing the size of each of the abrasive grains contained in the blade 32 when the upper first amorphous layers 3U are formed to be smaller than the size of each of the abrasive grains contained in the blade 32 when the lower first amorphous layers 3L are formed.

The blade 32 is the electroformed blade, for example, but is not limited to the electroformed blade. The blade containing abrasive grains each having a desired diameter can be selected as appropriate. The blade rotational speed is 10,000 rpm or more and 30,000 rpm or less. The blade feed speed is 5 μmm/see or more and 100 μmm/see or less. The blade rotational speed and the blade feed speed are adjusted as appropriate responsive to the blade material and the dicing apparatus. In Embodiment 3, the blade rotational speed is 20,000 rpm, and the blade feed speed is 20 μmm/sec.

In step S12, the upper second amorphous layers 4U and the lower second amorphous layers 4L are formed. The upper second amorphous layers 4U and the lower second amorphous layers 4L are formed when the SiC wafer 30 is diced along the transverse direction of the trench gates 15. In Embodiment 3, the dicing condition in step S12 is different from the dicing condition in step S11 as in Embodiment 1. The thickness of each of the second amorphous layers 4 is thus different from the thickness of each of the first amorphous layers 3. A method of forming the upper second amorphous layers 4U and the lower second amorphous layers 4L is similar to a method of forming the upper first amorphous layers 3U and the lower first amorphous layers 3L described above.

In Embodiment 3, the three-point bending test as shown in the schematic diagram of FIG. 34 was conducted on the semiconductor device 103 as in Embodiment 2. In a case where the three-point bending test is conducted on the first side surfaces 20 of the semiconductor device 103, the direction of extension of the trench gates 15 corresponds to the left-right direction in FIG. 34. The support span is 8 μmm. The indenter above the semiconductor device 103 is lowered toward the semiconductor device 103 at a speed of 0.5 μmm/min. The transverse strength was calculated based on the amount of deflection and the breaking load in this case.

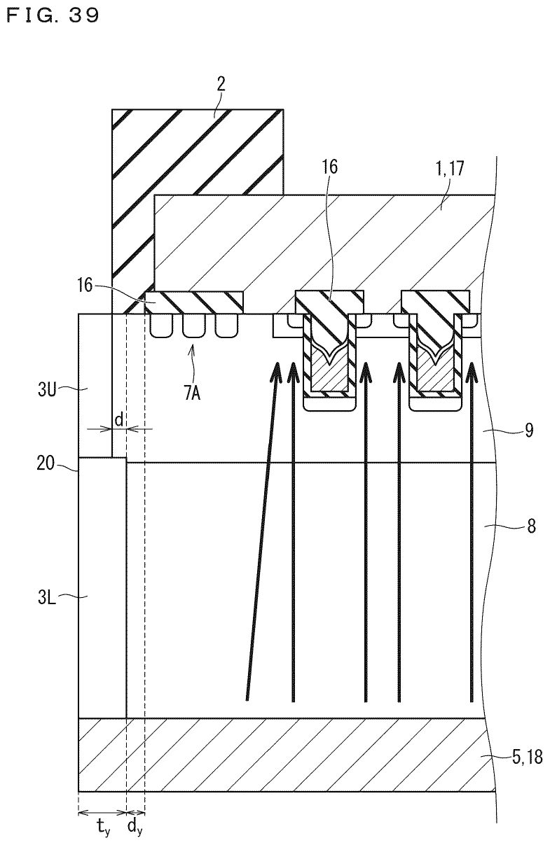

FIG. 39 is a diagram illustrating a configuration of an end portion of the semiconductor device 103 in a cross section orthogonal to the direction of extension of the trench gates 15. FIG. 39 shows a difference d in thickness between each of the upper first amorphous layers 3U and each of the lower first amorphous layers 3L in each of the first side surfaces 20 in addition to the thickness t_{y} of each of the lower first amorphous layers 3L and the distance d_{y} between each of the lower first amorphous layers 3L and the interlayer dielectric film 16. Furthermore, current flow in a case where the semiconductor device 103 is on is schematically shown by arrows in FIG. 39. The channels are formed near the trench gates 15, so that the current path does not expand.

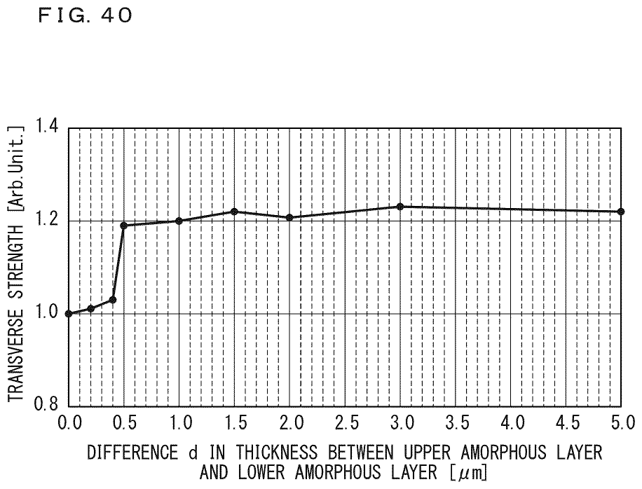

FIG. 40 is a diagram showing a relationship between the difference d in thickness between each of the upper first amorphous layers 3U and each of the lower first amorphous layers 3L in each of the first side surfaces 20 and the transverse strength of the semiconductor device 103. The transverse strength is normalized to a value in a case where the difference d in thickness is 0 μm. In a case where the difference d in thickness is 0.5 μm or more, a mechanical strength of the semiconductor device 103 is improved. While the difference d in thickness between each of the upper first amorphous layers 3U and each of the lower first amorphous layers 3L in each of the first side surfaces 20 and the transverse strength of the semiconductor device 103 were examined in FIG. 40, a similar result was obtained for a relationship between a difference d in thickness between each of the upper second amorphous layers 4U and each of the lower second amorphous layers 4L in each of the second side surfaces 21 and the transverse strength of the semiconductor device 103.

In Embodiment 2, the mechanical strength of the semiconductor device 102 is improved in a case where the width w of the single-crystal layer 4A is 2 μm or more as shown in FIG. 35. In Embodiment 3, it was confirmed that the mechanical strength of the semiconductor device 103 was improved in a case where a width of each of the upper first amorphous layers 3U was 2 μm or more.

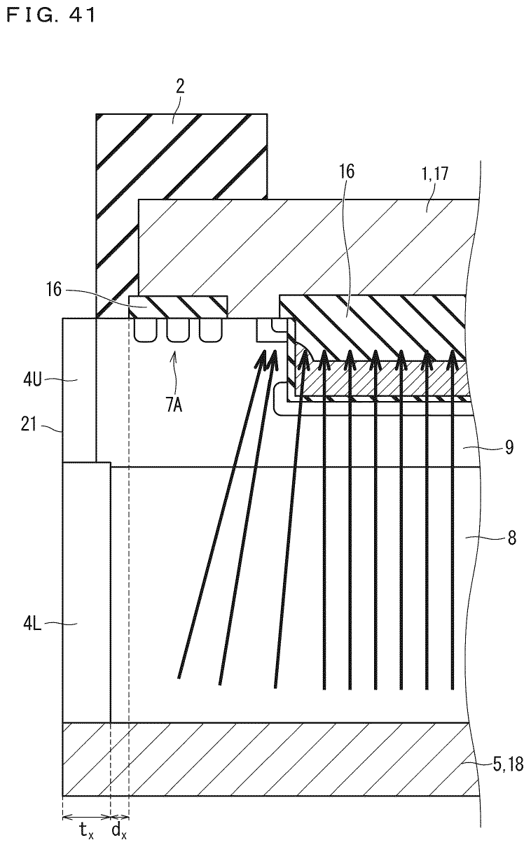

FIG. 41 is a diagram illustrating the configuration of the semiconductor device 103 in a cross section parallel to the direction of extension of the trench gates 15. A thickness tₓ of each of the lower second amorphous layers 4L and a distance dx between each of the lower second amorphous layers 4L and the interlayer dielectric film 16 are shown in FIG. 41. Furthermore, current flow in a case where the semiconductor device 103 is on is schematically shown by arrows in FIG. 41. The channels are formed near the trench gates 15, but a current flows to expand in the end portion of the trench gates 15. That is to say, portions around the trench gates 15 are portions of the current path.

Chip failure probability in Embodiment 3 is similar to that in the results shown in FIG. 27. A path of a current flowing from a back surface to a front surface of the semiconductor device 103 does not expand to an outer peripheral portion of the semiconductor device 103 as shown in each of FIGS. 39 and 41. The upper first amorphous layers 3U and the upper second amorphous layers 4U thus do not induce chip failure. As described above, the semiconductor device 103 according to Embodiment 3 has the enhanced chip strength while preventing breakage caused by switching operation. That is to say, the semiconductor device 103 has not only improved reliability but also the enhanced mechanical strength.

In the present disclosure, upper surface side amorphous layers are arranged in each of the first side surfaces 20 and the second side surfaces 21 of the semiconductor device 103. The upper surface side amorphous layers, however, are not necessarily required to be arranged in all the side surfaces of the semiconductor device 103 and may be arranged only in one of the side surfaces.

### Embodiment 4

In Embodiment 4, similar components to those in Embodiments 1 to 3 bear the same reference signs as those of the similar components, and detailed description thereof will be omitted.

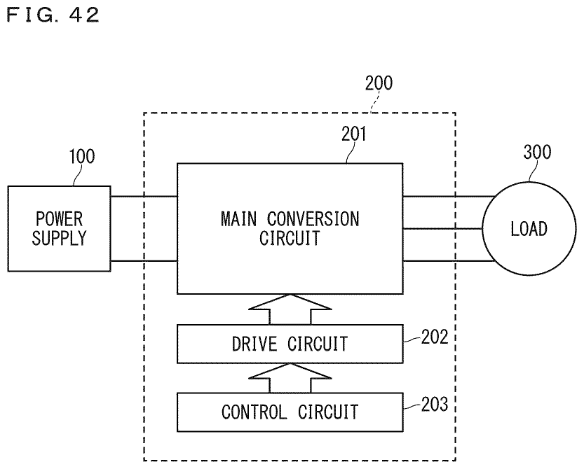

FIG. 42 is a block diagram showing configurations of a power converter 200 and a power conversion system according to Embodiment 4.

The power conversion system includes a power supply 100, the power converter 200, and a load 300.

The power supply 100 is a DC power supply. The power supply 100 supplies DC power to the power converter 200. The power supply 100 is configured by a DC system, a solar cell, a storage battery, and the like, for example. The power supply 100 may include a DC/DC converter that converts DC power output from the DC system into predetermined power. The power supply 100 may be configured by a rectifier circuit connected to an AC system, an AC/DC converter, and the like, for example.

The power converter 200 is a three-phase inverter connected between the power supply 100 and the load 300. The power converter 200 converts the DC power supplied from the power supply 100 into AC power and supplies the AC power to the load 300. A detailed configuration of the power converter 200 will be described below.

The load 300 is driven by the AC power supplied from the power converter 200. The load 300 in Embodiment 4 is a three-phase motor. The load 300, however, is not limited to a motor for a particular application. The load 300 may be a motor mounted on various types of electrical equipment. The motor is used for hybrid vehicles, electric vehicles, railroad vehicles, elevators, air-conditioning equipment, and the like, for example.

The power converter 200 will be described in detail below. The power converter 200 includes a main conversion circuit 201, a drive circuit 202, and a control circuit 203.

The main conversion circuit 201 converts the DC power into the AC power for output. The main conversion circuit 201 includes switching elements and freewheeling diodes (not shown). The switching elements are switched between on states and off states, so that the DC power supplied from the power supply 100 is converted into the AC power, and the AC power is supplied to the load 300. At least the switching elements or the freewheeling diodes of the main conversion circuit 201 are formed in the semiconductor device 101 shown in Embodiment 1 or the semiconductor device 102 shown in Embodiment 2. In other words, semiconductor elements included in each of the above-mentioned semiconductor devices 101 and 102 correspond to the switching elements or the freewheeling diodes of the main conversion circuit 201.

The main conversion circuit 201 in Embodiment 4 is a two-level three-phase full-bridge circuit. The main conversion circuit 201 includes six switching elements and six freewheeling diodes connected in anti-parallel with the respective switching elements. The main conversion circuit 201 includes upper and lower arms. One switching element that belongs to an upper arm is connected in series with one switching element that belongs to a lower arm. In other words, every two switching elements out of the six switching elements are connected in series with each other to constitute pairs of upper and lower arms. The pairs of upper and lower arms constitute respective phases (a U phase, a V phase, and a W phase) of the full-bridge circuit. Three-phase output terminals, that is, three output terminals of the main conversion circuit 201 are connected to the load 300. A circuit configuration of the main conversion circuit 201 is one example and is not limited to the above-mentioned configuration.

The drive circuit 202 generates a drive signal to control a state of each of the switching elements of the main conversion circuit 201. The drive circuit 202 outputs the drive signal to a control electrode of each of the switching elements of the main conversion circuit 201. Specifically, to the control electrode of each of the switching elements, a drive signal to switch the switching element to an on state and a drive signal to switch the switching element to an off state are output responsive to a control signal output from the control circuit 203. The drive signal is a voltage signal (an on signal) equal to or greater than a threshold voltage of the switching element when the switching element is maintained in the on state. The drive signal is a voltage signal (an off signal) equal to or smaller than the threshold voltage of the switching element when the switching element is maintained in the off state. In a case where the switching element is a MOSFET or an IGBT, the control electrode is the gate electrode 14.

The control circuit 203 outputs the control signal to control the drive circuit 202. The control signal is controlled so that predetermined power is supplied to the load 300. Specifically, the control circuit 203 calculates time during which each of the switching elements of the main conversion circuit 201 is to be in the on state, that is, on time based on power to be supplied to the load 300. The control circuit 203 generates and outputs the control signal so that the on signal is output from the drive circuit 202 to each of the switching elements at a timing when the switching element is to be in the on state and the off signal is output from the drive circuit 202 to the switching element at a timing when the switching element is to be in the off state. In other words, the control circuit 203 performs PWM control to modulate the on time responsive to a voltage to be output.

In the power converter 200 having such a configuration, the semiconductor device 101 according to Embodiment 1 or the semiconductor device 102 according to Embodiment 2 is applied to each of the switching elements of the main conversion circuit 201, so that reliability is improved.

While an example in which the above-mentioned semiconductor devices 101 and 102 are applied to a two-level three-phase inverter is shown in Embodiment 4, a target of application of the semiconductor devices 101 and 102 is not limited to the two-level three-phase inverter, and the semiconductor devices 101 and 102 are applied to various power converters. The semiconductor devices 101 and 102 are applicable to a three-level or multi-level power converter. In a case where the power converter 200 supplies power to a single-phase load, the semiconductor devices 101 and 102 may be applied to a single-phase inverter. In a case where the power converter 200 supplies power to a DC load and the like, the semiconductor devices 101 and 102 may be applied to a DC/DC converter or an AC/DC converter.

A target of control of the power converter 200 is not limited to the motor. The power converter 200 may control conversion of power in an electrical discharge machine, a laser machine, an induction cooker, a noncontact power supply system, and the like, for example. The power converter 200 may be applied to a power conditioner of a photovoltaic generation system, a storage system, and the like, for example.

Embodiments of the present disclosure can freely be combined with each other and can be modified or omitted as appropriate.

### EXPLANATION OF REFERENCE SIGNS

1 front surface electrode, 2 outer peripheral insulating layer, 3 first amorphous layer, 4 second amorphous layer, 4A single-crystal layer, 5 back surface electrode, 6 transistor region, 7 termination region, 7A breakdown voltage holding structure, 8 n type SiC layer, 9 n type drift layer, 10 p type base layer, 11 n type source layer, 12 p type bottom base layer, 13 gate dielectric film, 14 gate electrode, 14A oxidation layer, 15 trench gate, 16 interlayer dielectric film, 17 source electrode, 18 drain electrode, 19 gate connecting portion, 20 first side surface, 21 second side surface, 22 first lead, 23 solder, 24 second lead, 25 wire, 30 n type SiC wafer, 31 semiconductor substrate, 32 blade, 100 power supply, 101 semiconductor device, 102 semiconductor device, 200 power converter, 201 main conversion circuit, 202 drive circuit, 203 control circuit, 300 load.

1. A semiconductor device comprising:
a semiconductor substrate that includes a semiconductor element being at least one of a transistor and a diode;
a trench gate that includes an electrode to control a state of the semiconductor element and is provided in an upper surface of the semiconductor substrate;
a first amorphous layer that is disposed in each of two opposing first side surfaces from among four side surfaces of the semiconductor substrate; and
a second amorphous layer that is disposed in each of two opposing second side surfaces other than the first side surfaces from among the four side surfaces of the semiconductor substrate, wherein
in plan view, a first angle between each of the first side surfaces and a direction of extension of the trench gate is smaller than a second angle between each of the second side surfaces and the direction of extension of the trench gate, or each of the first side surfaces is parallel to the direction of extension of the trench gate, and
a thickness of the first amorphous layer in a direction from each of the first side surfaces toward an inside of the semiconductor substrate is different from a thickness of the second amorphous layer in a direction from each of the second side surfaces toward the inside of the semiconductor substrate.

2. The semiconductor device according to claim 1 further comprising:
a breakdown voltage holding structure that is disposed to surround a region in which the semiconductor element is disposed and holds a breakdown voltage of the semiconductor element;
a front surface electrode that is disposed over the upper surface of the semiconductor substrate and is electrically connected to the semiconductor element; and
an interlayer dielectric film that is disposed between a lower surface of the front surface electrode and the upper surface of the semiconductor substrate and covers the breakdown voltage holding structure, wherein
the first amorphous layer and the second amorphous layer are arranged outside the interlayer dielectric film in plan view and are separated from an outer edge of the interlayer dielectric film by 3 μm or more.

3. The semiconductor device according to claim 1, wherein
the thickness of the second amorphous layer is less than or equal to 1.1 times the thickness of the first amorphous layer.

4. The semiconductor device according to claim 1, wherein
the thickness of the first amorphous layer is 0.05 μm or more.

5. The semiconductor device according to claim 1 further comprising
a single-crystal layer that is disposed above the second amorphous layer in each of the second side surfaces.

6. The semiconductor device according to claim 1, wherein
the first amorphous layer and the second amorphous layer are formed of an amorphous material including the same element as an element forming a crystal of the semiconductor substrate.

7. The semiconductor device according to claim 1, wherein
the semiconductor substrate includes a drift layer,
the first amorphous layer includes an upper first amorphous layer that is disposed in a side surface of the drift layer and a lower first amorphous layer that is disposed closer to a lower surface of the semiconductor substrate than the upper first amorphous layer is,
the second amorphous layer includes an upper second amorphous layer that is disposed in a side surface of the drift layer and a lower second amorphous layer that is disposed closer to the lower surface of the semiconductor substrate than the upper second amorphous layer is, and
a thickness of the upper first amorphous layer in the direction from each of the first side surfaces toward the inside of the semiconductor substrate is smaller than a thickness of the lower first amorphous layer in the direction from each of the first side surfaces toward the inside of the semiconductor substrate.

8. The semiconductor device according to claim 1, wherein
the semiconductor substrate includes a drift layer,
the first amorphous layer includes an upper first amorphous layer that is disposed in a side surface of the drift layer and a lower first amorphous layer that is disposed closer to a lower surface of the semiconductor substrate than the upper first amorphous layer is,
the second amorphous layer includes an upper second amorphous layer that is disposed in a side surface of the drift layer and a lower second amorphous layer that is disposed closer to the lower surface of the semiconductor substrate than the upper second amorphous layer is, and
a thickness of the upper second amorphous layer in the direction from each of the second side surfaces toward the inside of the semiconductor substrate is smaller than a thickness of the lower second amorphous layer in the direction from each of the second side surfaces toward the inside of the semiconductor substrate.

9. A power converter comprising:
a main conversion circuit that converts input power for output, the main conversion circuit including the semiconductor device according to claim 1;
a drive circuit that outputs a drive signal to drive the semiconductor device to the electrode of the semiconductor element of the semiconductor device; and
a control circuit that outputs a control signal to control the drive circuit to the drive circuit.

10. The semiconductor device according to claim 7, wherein
a thickness of the upper second amorphous layer in the direction from each of the second side surfaces toward the inside of the semiconductor substrate is smaller than a thickness of the lower second amorphous layer in the direction from each of the second side surfaces toward the inside of the semiconductor substrate.
